(19) United States
(12) Patent Application Publication
(10) Pub. No.: US 2026/0349025 A1
(43) Pub. Date: Nov. 5, 2026

(54) SYSTEMS AND METHODS FOR DETECTING FAILURE OF SEMICONDUCTOR DEVICES

(71) Applicant: Taiwan Semiconductor Manufacturing Company, Ltd., Hsinchu (TW)

(72) Inventors: Wei-Jheng Syu, Hsinchu (TW); Sheng-Hsiu Lee, Hsinchu (TW); Yen-Po Chen, Hsinchu (TW)

(73) Assignee: Taiwan Semiconductor Manufacturing Company, Ltd., Hsinchu , (TW)

(21) Appl. No.: 19/197,024

(22) Filed: May 2, 2025

(51) Int. Cl. G01R 31/28; H02M 1/00

(52) U.S. Cl. CPC G01R 31/2843; G01R 31/2848; H02M 1/0009

(57) ABSTRACT

An apparatus includes a power conversion circuit including a plurality of switches, each of the plurality of switches having three terminals; and a detection circuit operatively coupled to the power conversion circuit. The detection circuit to: retrieve a first current signal (I_{Uav}), a second current signal (I_{Vav}), and a third current signal (I_{Wav}), wherein the first current signal is provided by a first pair of the plurality of switches, the second current signal is provided by a second pair of the plurality of switches, and the third current signal is provided by a third pair of the plurality of switches; convert the first to third current signals into two orthogonal components; generate a first plot and a second plot each based on the two orthogonal components; and detect an anomaly associated with at least one of the plurality of switches based on comparing the first plot and the second plot.

### BACKGROUND

Modern UPS systems incorporate sophisticated power conversion technologies to ensure continuous operation during power disturbances, protecting sensitive electronic equipment from voltage fluctuations, surges, and outages. Some of the advancements have been the results of improvements in power semiconductor devices, such as insulated gate bipolar transistors (IGBTs), which offer high efficiency and fast switching characteristics.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a schematic diagram of an example system for detecting failure of semiconductor devices, in accordance with some embodiments.

FIG. 2 illustrates example plots of simulated and/or measured amplitudes of current waveforms from the system of FIG. 1, in accordance with some embodiments.

FIG. 3 illustrates an example flow chart of a method for detecting failure of the semiconductor devices, in accordance with some embodiments.

FIG. 4 illustrates an example structure including a power conversion circuit of the example system of FIG. 1 bonded to a heatsink, in accordance with some embodiments.

FIG. 5 illustrates a block diagram of a thermal model of the example structure in FIG. 4, in accordance with some embodiments.

FIG. 6 illustrates an example graph of the relationship between the current signal and the junction temperature associated with the example structure of FIG. 4, in accordance with some embodiments.

FIGS. 7-10 illustrate Bode plots for analyzing the health status of one or more insulated gate bipolar transistors (IGBTs) in a power conversion circuit of the example system of FIG. 1, in accordance with some embodiments.

FIG. 11 illustrates an overview of analysis techniques executed by the example system of FIG. 1 for detecting failure of the semiconductor devices, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In general, the reliability and efficiency of electrical systems can be enhanced or ensured by using uninterruptible power supplies (UPS), variable frequency drives (VFD), or other components or devices. Such electrical systems may rely on power components such as insulated gate bipolar transistors (IGBTs) to manage and distribute power. The IGBTs can be semiconductor devices that are parts of the UPS and/or VFD units, for example. The IGBTs can combine the high input impedance of metal-oxide-semiconductor field-effect transistors (MOSFETs) with the low on-state conduction losses of bipolar junction transistors (BJTs), implemented for various applications, including but not limited to high-voltage or high-current applications. Structurally, the IGBT can include a four-layer (PNPN) configuration with three terminals, e.g., gate, collector, and emitter. The gate can be referred to as a gate terminal, contact, or electrode. The collector and emitter may each be referred to as a source/drain (S/D) terminal or electrode. The IGBTs can operate by using a voltage applied to the gate to control current flow between the S/D terminals (e.g., between the collector and emitter).

Despite the IGBTs being implemented to support the operations of various electrical systems, the IGBTs may lack preventive maintenance strategies, relying on hardware detection mechanisms. Such mechanisms may be considered as lagging indicators, responding to faults after their occurrences, instead of preventing the faults. For example, certain maintenance approaches may trigger a fault indicator after the electrical system experienced issues, instead of detecting faults in the IGBTs operations. In such cases, reliance on reactive measures may pose risks to the system operation and safety of the electrical systems.

In another example, certain detection mechanisms may lack the capability to analyze or detect component aging and variation which may lead to component (e.g., IGBT) failure. Certain systems that depend solely on rapid hardware detection and protection mechanisms, may lack the capability to ensure long-term reliability. Overvoltage and overcurrent detection mechanisms, for example, may trigger shutdowns of at least a portion of an electrical system through hardware loops, which can disrupt operational equipment and lead to downtime. In some cases, certain other detection mechanisms may trigger shutdowns, such as certain temperature detection mechanisms. It may be challenging to predict and prevent failures before their occurrences with the reactive response to faults, which lack insights into the gradual degradation of components.

To address these challenges, the systems and methods of the technical solution can integrate and deploy a model (e.g., formulas or mechanisms) with various detection mechanisms to perform fault/failure detection or prediction of one or more components, such as but not limited to IGBTs of an electrical system (e.g., power conversion circuit). The systems and methods can involve components to perform at least one of current analysis (or computation), temperature analysis, or voltage spectrum analysis, among others. The current analysis can involve or utilize current transformation to detect potential abnormalities of power components (e.g., IGBTs) by analyzing magnitudes and (phase) angles from current measurements. The temperature analysis can leverage data sets to establish standard values and allowable deviations by collecting and analyzing current and temperature data. The voltage spectrum analysis can record the voltage spectrum (e.g., Bode plot) and compute frequency deviations under component variation. The systems and methods can leverage these components individually or in combination, for instance, at least one or a combination of the current analysis, temperature analysis, and/or voltage spectrum analysis technique, among others. By implementing the technique(s) discussed herein, the systems and methods can achieve an early-stage IGBT health index approach to monitor and evaluate the health (or operating condition) of the IGBTs prior to failure. The systems and methods can intercept anomalies before system or component failures, allowing/enabling preemptive inspections of the electrical systems, component replacements, or other remedies to reduce downtime, improve safety and reliability of the electrical systems, enhance operational efficiency, etc.

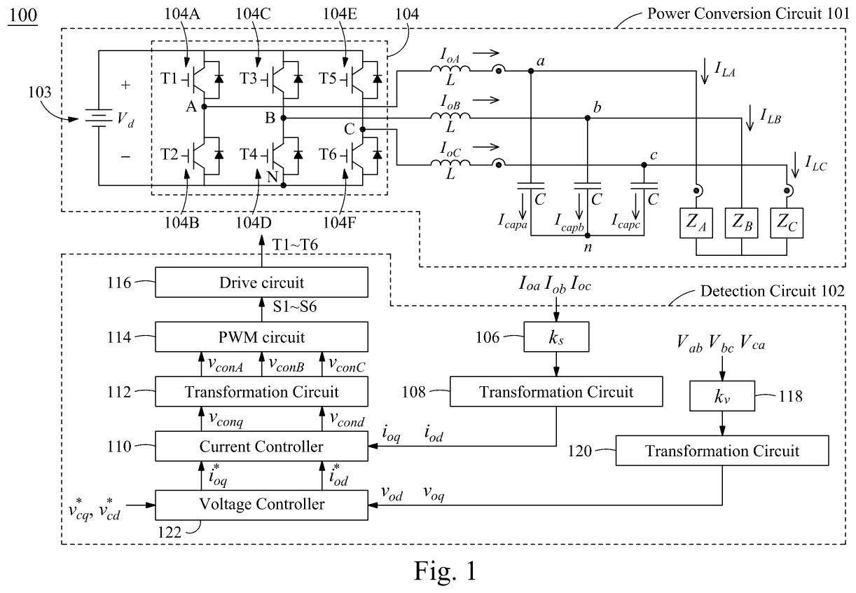

FIG. 1 illustrates a schematic diagram of an example system 100 for detecting failure of semiconductor devices, in accordance with some embodiments. The components or circuits of the system 100 can be part of a single device or multiple devices operatively coupled to each other. The system 100 can include various components, such as but not limited to a power conversion circuit 101 and a detection circuit 102. The components of the system 100 (e.g., components of the detection circuit 102) can operate or perform features or functions to detect or determine potential faults in the power conversion circuit 101.

The power conversion circuit 101 can include, correspond to, or be implemented in one or more electrical systems, such as a UPS or a VFD. The power conversion circuit 101 can include or be composed of one or more hardware components configured to execute or perform one or more functions discussed herein. For example, the power conversion circuit 101 can operate to convert electrical power from one form to another, such as from alternating current (AC) to direct current (DC) or vice versa. The power conversion by the power conversion circuit 101 can be implemented to ensure proper functioning and reliability of the electrical systems.

As an example, in the context of a UPS, the power conversion circuit 101 may include components such as rectifiers, inverters, or filters. The power conversion circuit 101 (e.g., rectifier) can convert incoming AC power from a power supply into DC power for charging the UPS battery. During a power outage, the power conversion circuit 101 (e.g., inverter) can covert the stored DC power from the battery back into AC power to supply the connected equipment, ensuring a continuous power supply without interruption.

In another example, in the context of a VFD, the power conversion circuit 101 can, in part, control or support controlling the speed of electric motors by varying the frequency of the power supplied to the electric motor. The power conversion circuit 101 may include, for instance, a rectifier, a DC link, and/or an inverter. The power conversion circuit 101 (e.g., rectifier) can convert the incoming AC power to DC power, which can then be smoothed and stored in the DC link, for example. The power conversion circuit 101 (e.g., inverter) can convert the DC power back to AC power with a variable frequency and voltage, which can be used to control the speed and torque of the motor. It should be noted that the power conversion circuit 101 can be used for other purposes or implemented in various other applications not limited to those discussed herein.

The power conversion circuit 101 can include a power supply 103 (e.g., power source), a plurality of switches 104, inductors, capacitors, or other components. The power conversion circuit 101 can be electrically or operatively coupled to one or more loads (e.g., Z_{A}, Z_{B}, and Z_{C}). the power supply 103 can provide the necessary power or voltage to operate the components of the power conversion circuit 101. In some cases, the power conversion circuit 101 may include additional power supplies. In some other cases, the power supply 103 may be an external power supply, separate from the power conversion circuit 101.

In some configurations, the power conversion circuit 101 can include six switches 104 (e.g., switches 104A-F). The switches 104 may be labeled as T1-T6, as shown in at least FIG. 1. The switches 104 may be referred to as transistors 104. The power conversion circuit 101 may include more or fewer number of switches 104, not limited to six switches 104, for instance, to function as a power converter. The switches 104 can include, correspond to, or be implemented using IGBTs. The switches 104 (e.g., IGBTs) can regulate the flow of current through the power conversion circuit 101.

Individual switches 104 can include three terminals, e.g., similar to metal-oxide-semiconductor (MOS) transistors. The three terminals can include a gate terminal, a first S/D terminal (e.g., collector), and a second S/D terminal (e.g., emitter). The switches 104 can be configured to provide three-phase current (e.g., I_{oA}, I_{oB}, and I_{oC}). The switches 104 can be controlled by respective gate signals to turn on and off, thereby regulating the current flow through the circuit. The gate signals can be provided by one or more components of the detection circuit 102 or other circuits in the system 100.

Turning on the switch 104 can involve applying a predetermined voltage level at the gate terminal of the switch 104. By turned on, the switch 104 can allow current to flow between the S/D terminals. Turning off the switch 104 can involve stopping or preventing the voltage from being applied at the gate terminal of the switch 104, or in some cases, applying a relatively low voltage level (below the predetermined voltage level) at the gate terminal, for example. When turned off, the switch 104 may not allow current to flow between the S/D terminals.

The switches 104 can be turned on and off to convert the input power supplied from the power supply 103 to the desired output form. The switches 104 can be arranged in a three-phase bridge configuration including three legs (extending from respective nodes A-C, at least to the load impedances Z_{A-C}). The one or more switches 104 can operate to generate three-phase current, which may be spaced 120 degrees apart. Each of the three legs can correspond to one phase of the three-phase system (e.g., phases A-C). Each leg is associated with a pair of switches. Switches 104A-F can be referred to as T1-T6, respectively. For example, T1 and T2 (e.g., first pair of switches 104) can be electrically connected at node “A” to operatively form a first phase leg. T3 and T4 (e.g., second pair of switches 104) can be electrically connected at node “B” to operatively form a second phase leg. T5 and T6 (e.g., third pair of switches 104) can be electrically connected at node “C” to operatively form a third phase leg. T1, T3, and T5 can be referred to as high-side switches. T2, T4, and T6 can be referred to as low-side switches. Current for the phases A-C can flow via the nodes A-C, respectively.

In operation, for phase A current, when T1 is on and T2 is off, the current (e.g., I_{oA}) can flow from the positive DC bus (of the power supply 103) through T1, through the load Z_{A}, and return to the negative DC bus. This can create a positive half-cycle for phase A. When T1 is off and T2 is on, the current can flow from the negative DC bus through T2, through the load Z_{A}, and return to the positive DC bus, thereby creating a negative half-cycle for phase A. For phase B current, when T3 is on and T4 is off, the current (e.g., I_{oB}) can flow from the positive DC bus through T3, through the load Z_{b}, and return to the negative DC bus, creating a positive half-cycle for phase B. When T3 is off and T4 is on, the current can flow from the negative DC bus through T4, through the load Z_{b}, and return to the positive DC bus, creating a negative half-cycle for phase B.

In further operations, for phase C, when T5 is on and T6 is off, the current (I_{oC}) can flow from the positive DC bus through T5, through the load Z_{c}, and return to the negative DC bus, creating a positive half-cycle for phase C. When T5 is off and T6 is on, the current can flow from the negative DC bus through T6, through the load Z_{c}, and return to the positive DC bus, creating a negative half-cycle for phase C. It should be noted that the loads Z_{A}, Z_{B}, and Z_{c} can include or correspond to any resistive, inductive, or capacitive elements that the power conversion circuit 101 drives. The loads can receive the current from the switches and represent the load impedances in a three-phase system. The values of the load impedances can affect the current and voltage characteristics of the power conversion circuit 101.

The indicators (e.g., L) of the power conversion circuit 101 can be used at least to store energy in the form of a magnetic field and/or to smooth out the current flow, e.g., each inductor may function as a filter, filtering current ripples and providing a relatively more stable output. The capacitors (e.g., C) of the power conversion circuit 101 can be used at least to store energy in the form of an electric field and to smooth out the voltage. For instance, each capacitor may function as another filter to filter voltage ripples and provide a relatively more stable output voltage. In some configurations, the power conversion circuit 101 can include other types of switches for the three-phase system.

The power conversion circuit 101 can include sensors or other types of monitoring devices to obtain measurement data for analysis. For example, the power conversion circuit 101 can include current sensors, voltage sensors, temperature sensors, etc. The current sensors can monitor the input and output currents associated with the switches 104. The temperature sensors can monitor the temperature of one or more components of the power conversion circuit 101. The voltage sensors can monitor the voltage levels (e.g., DC or AC voltage levels) in the power conversion circuit 101. The sensor data generated by the sensors can be provided in real-time to the detection circuit 102, among other circuits or devices. The sensor data can be used, at least in part, to detect or determine any anomalies within the power conversion circuit 101 or initiate at least one action to prevent failures, for example.

The power conversion circuit 101 can be operatively coupled to the detection circuit 102 detect potential faults, for instance, caused by an open circuit or a short circuit of at least one of the switches 104. The detection circuit 102 can be configured to detect the fault before failure or shutdown of the power conversion circuit 101 to minimize downtime, improve safety, and increase efficiency and reliability of the power conversion circuit 101 (or other circuits being tested or analyzed).

The detection circuit 102 can include or be composed of one or more hardware components. The detection circuit 102 can be a remote circuit from the power conversion circuit 101. The detection circuit 102 can operatively couple to the power conversion circuit 101 via one or more wired or wireless connections. In some cases, the detection circuit 102 and the power conversion circuit 101 can be parts of a device. The detection circuit 102 can include one or more components to perform the fault detection, including at least one interface circuit 106, 118, at least one transformation circuit 108, 112, 120, at least one current controller 110, at least one pulse width modulation (PWM) circuit 114, at least one drive circuit 116, at least one voltage controller 122, or other components for detecting potential faults in the power conversion circuit 101, e.g., related to the operations of at least one of the switches 104. In some configurations, the components of the detection circuit 102 can be individual or separate components configured to jointly perform operations discussed herein for fault/failure detection. In some other configurations, the components of the detection circuit 102 can represent functions of a single component for the fault detection.

The detection circuit 102 may include more or less components, not limited to those provided in conjunction with FIG. 1. For example, to perform fault detection using current data or waveform (e.g., current analysis), the detection circuit 102 may not include or may not utilize the interface circuit 118, the transformation circuit 120, and/or the voltage controller 122. In another example, to perform fault detection using voltage data or waveform (e.g., voltage spectrum analysis), the detection circuit 102 may not include or may not utilize the interface circuit 106, the transformation circuit 108, and/or the current controller 110. In further examples, to perform fault detection using temperature data (e.g., temperature analysis), the detection circuit 102 may include one or more additional components to interface with (and receive data from) the power conversion circuit 101 or process the temperature data to perform the fault or anomaly detection.

The interface circuit 106 can be configured to interface or communicate with one or more circuits, devices, or components to receive signals or data for processing, e.g., current signals, voltage signals, etc. In some cases, the interface circuit 106 can provide data to other circuits within the system 100. For example, the interface circuit 106 can receive the three-phase current values or signals (e.g., Iₒₐ, I_{ob}, and I_{oc}) from the power conversion circuit 101. Each current signal can be provided by a respective pair of switches 104. For instance, a first current signal (Iₒₐ) can be provided by a first pair of switches (e.g., T1 and T2). A second current signal (I_{ob}) can be provided by a second pair of switches (e.g., T3 and T4). A third current signal (I_{oC}) can be provided by a third pair of switches (e.g., T5 and T6). The current signal can be referred to interchangeably with current values, in some cases. The current values can be measured current values or simulated current values. The interface circuit 106 may receive the measured current values from one or more sensors (e.g., current sensors) monitoring the three-phase current in the power conversion circuit 101 at the three legs (associated with nodes A-C). In some cases, the interface circuit 106 can include the one or more sensors configured to capture or measure the current values. The interface circuit 106 can receive the current values measured during the operation of the power conversion circuit 101 for at least a predetermined timeframe.

The interface circuit 106 can receive current values simulated for the power conversion circuit 101. The interface circuit 106 may receive the simulated current values from an external device (e.g., simulation device) executing a simulation of the power conversion circuit 101. The simulated values, e.g., current values, voltage values, or other information, can be based on the specific configuration of the circuit being simulated. In this case, the simulation can be based on the three-phase system having the six switches 104, where current values can be obtained at the respective legs (each leg associated with a respective phase 120 degrees apart). For example, the simulation can provide current values at each leg of the three-phase system. The simulated values can represent the predicted (or expected) electrical current flowing through each leg of the power conversion circuit 101, for instance, based on the configuration of the circuit and the condition or status of the one or more components.

In some configurations, the interface circuit 106 can obtain simulated current values for the power conversion circuit 101 with the switches 104 operating as intended (e.g., operating normally or with no fault). The interface circuit 106 can receive a plurality of simulated current values during operations. The operations of the power conversion circuit 101 can involve alternatively activating (e.g., turning on) or deactivating (e.g., turning off) individual switches 104. The interface circuit 106 can provide the simulated values of the power conversion circuit 101 under normal condition to the transformation circuit 108.

In some configurations, the interface circuit 106 can obtain simulated current values for the power conversion circuit 101 with at least one switch 104 having a fault, e.g., at least one of the switches 104 experiencing or in an open circuit or short circuit condition. In this case, the simulated current values may be referred to as fault simulated current values, open circuit simulated current values, or short-circuit simulated current values, for example.

The interface circuit 106 can receive or retrieve the open circuit simulated current values by simulating an open circuit on individual switches 104. When a switch is an open circuit, current may not be conducted from one S/D terminal to another. The open circuit condition can be simulated for individual switches 104 by blocking or not applying voltage at the gate (e.g., no gate signal, hence no current flow through the respective switch). For example, during the operation of the power conversion circuit 101 in the simulation, individual switches 104 can be set to an open circuit for a relatively brief or short time. The three-phase current values can be captured when a respective switch is set to be an open circuit. For instance, with six switches 104, the interface circuit 106 can receive at least six sets of simulated current values.

The interface circuit 106 can receive or retrieve the short-circuit simulated current values by simulating a short circuit on individual switches 104. To simulate the short circuit, a short circuit route (e.g., a wire or connection) can be provide in the simulation, connecting one S/D terminal of a respective switch to other parts of the circuit. For instance, to simulate the short-circuit for T1, a short circuit route can be placed from one S/D terminal to another. In another example, the short circuit route may be placed from the collector (or drain) of T1 to the emitter (or source) of T2, or other portions of the power conversion circuit 101, to simulate short-circuit for T1. The simulation of a short-circuit can be applied to other switches 104. The interface circuit 106 can receive sets of three-phase current values associated with the shorting of individual switches 104.

In some other cases, a short circuit can be simulated for a switch by maintaining the switch in an on state, throughout the operation of the power conversion circuit 101. Other non-limiting techniques or configurations can be implemented to perform the simulations. The current values (e.g., simulated or measured) can be utilized to determine potential faults or anomalies within the power conversion circuit 101. The interface circuit 106 can process the received current values and provide the processed current values as inputs to the transformation circuit 108. Processing the current values may involve applying data filter or converting data format, for example. In some cases, the interface circuit 106 may forward the current values to the transformation circuit 108 without processing.

The transformation circuit 108 can receive the (simulated or measured) current signals or data from the interface circuit 106. The transformation circuit 108 can convert the three-phase current values (e.g., first to third current signals) into two orthogonal components (or values), e.g., i_{oq} (e.g., I_{Qav}) and I_{od} (e.g., I_{Dav}). The transformation circuit 108 can use example formula (1) to compute or derive the two orthogonal components from each set of current values.

$${I}_{Dav} = \frac{\sqrt{2}}{\sqrt{3}} {I}_{Uav} - \frac{1}{\sqrt{6}} {I}_{Vav} - \frac{1}{\sqrt{6}} {I}_{Wav} , {I}_{Qav} = \frac{1}{√ 2} {I}_{Vav} - \frac{1}{\sqrt{2}} {I}_{Uav} + {I}_{Q 0} , \qquad ( 1 )$$

$${I}_{Uav} = {I}_{oa} , {I}_{Vav} = {I}_{ob} , {I}_{Qav} = {I}_{oc} , {I}_{Dav} = {i}_{od} , {I}_{Qav} = {i}_{oq}$$

The individual sets of current values can be captured during different activation or deactivation of the switches 104 in the power conversion circuit 101. For purposes of providing examples, there may be at least six sets of current values (e.g., measured or simulated), each for respective activation of a particular switch. The orthogonal components (e.g., i_{od} and i_{oq}) can be vectors that are perpendicular to each other in a given space. The orthogonal components can refer to parts of a signal that do not interfere with each other.

The transformation circuit 108 can process other information from the interface circuit 106. The transformation circuit 108 can perform other processing techniques not limited to determining the orthogonal components. The transformation circuit 108 can provide the orthogonal components to the current controller 110 for processing and determining whether there are potential faults or anomalies. For instance, the transformation circuit 108 can generate, compute, or otherwise drive the orthogonal components from the simulated current signals when the power conversion circuit 101 is operating as intended (e.g., operating normally without faults). The transformation circuit 108 can derive the orthogonal components from the simulated current signals when at least one of the switches 104 is in an open circuit condition. The transformation circuit 108 can derive the orthogonal components from the simulated current signals when at least one of the switches 104 is in a short circuit condition. The transformation circuit 108 can derive the orthogonal components from the measured current signals during operation of the power conversion circuit 101.

The current controller 110 can receive the orthogonal components from the transformation circuit 108. The current controller 110 can process the orthogonal components to derive generate a vector having a magnitude or amplitude (e.g., I_{Sav}) of the current signals and the phase angle (e.g., ∠θ_{Sav}) associated with the amplitude. For instance, the current controller 110 can derive the amplitudes and phase angles for during the operation of the power conversion circuit 101 using or based on example formula (2). The output from applying the example formula (1) can be used as inputs to the example formula (2).

$${I}_{Sav} = \sqrt{{1}_{Dav}^{2} + {I}_{Qav}^{2}} , {∠θ}_{Sav} = arctan \frac{{I}_{Qav}}{{I}_{Dav}} \qquad ( 2 )$$

The current controller 110 can iteratively process the two orthogonal components from various conditions (e.g., simulated or actual) of the power conversion circuit 101. For example, the current controller 110 can generate the amplitude and phase angle from the orthogonal components associated with the simulated current signals (e.g., under normal operation, open circuit, or short-circuit). In another example, the current controller 110 can generate the amplitude and phase angle from the orthogonal components associated with the measured current signals.

The current controller 110 can generate tables according to the amplitudes and phase angles derived from the simulated values. For purposes of providing examples, the current controller 110 can generate a first table (e.g., example Table 1) for the simulation of open circuits and a second table (e.g., example Table 2) for the simulation of close circuits. The values in the tables are provided as example values, and should not be limited to those presented herein. The tables can include the amplitudes, phase angles, and phase ranges associated with individual amplitudes and phase angles.

The phase range can represent a range of phase angles that is associated with a particular switch. With six switches 104, for example, there are six phase ranges, each having a range of 60 degrees. The phase ranges can be predetermined, e.g., a range between 30-90, 90-150, 150-210, 210-270, 270-330, and 330-30 degrees, for example. The current controller 110 can determine which of the switches 104 belong to a respective phase range based on the computed phase angle, e.g., according to the type of simulated fault.

For example, the example Table 1 can represent a simulation of the current when one of the switches T1-T6 is intentionally opened for a relatively brief period (e.g., each switch is simulated as an open circuit individually). The individual columns of the example Table 1 can correspond to when the respective switch is intentionally opened (e.g., the switch experiencing an open circuit fault). In this case, when T1 is open (in the simulation), the current controller 110 may compute the phase angle as 112 degrees, which is within the 90 to 150 degrees range. When T2 is open, the current controller 110 may compute the phase angle as 291 degrees, which is within the 270 to 330 degrees range. The process can be repeated for the other switches, as provided in the example Table 1.

In further examples, the example Table 2 can represent a simulation of the current when one of the switches T1-T6 is intentionally shorted for a relatively brief period (e.g., each switch is simulated as a short circuit individually). Similar to Table 1, the individual columns of the example Table 1 can correspond to when the respective switch is intentionally shorted (in the simulation). In this case, when T1 is shorted (in the simulation), the current controller 110 may compute the phase angle as 345 degrees, which is within the 330 to 30 degrees range. When T2 is shorted, the current controller 110 may compute the phase angle as 167 degrees, which is within the 150 to 210 degrees range. The process can be repeated for the other switches, as provided in the example Table 2.

According to the simulation of the open circuit or short circuit, the current controller 110 can determine individual switches 104 associated with the respective phase ranges, e.g., as shown in the tables for purposes of providing examples. In some cases, the current controller 110 may generate a mapping (e.g., instead of a table) to map individual phase ranges to the respective switches 104 according to the computed phase angle when the switch is either open or shorted, for example. The current controller 110 can execute other techniques to link or associate individual switches to respective phase ranges. The current controller 110 can use the phase ranges to associate a potential fault to at least one of the switches 104.

Example Table 1 - Open Circuit

| Open | | | | | | |
|---|---|---|---|---|---|---|
| Circuit | T1 | T2 | T3 | T4 | T5 | T6 |
| Magni- | 3.54 | 3.52 | 3.53 | 3.53 | 3.52 | 3.54 |
| tude or | | | | | | |
| Ampli- | | | | | | |
| tude | | | | | | |
| Phase | 112 | 291 | 230 | 51 | 351 | 170 |
| Angle | | | | | | |
| Phase | 90~150 | 270~330 | 210~270 | 30~90 | 330~30 | 150~210 |
| Range | | | | | | |

Example Table 2 - Short Circuit

| Open | | | | | | |
|---|---|---|---|---|---|---|
| Circuit | T1 | T2 | T3 | T4 | T5 | T6 |
| Magni- | 267.4 | 248.1 | 241.4 | 255.8 | 258.2 | 257.9 |
| tude or | | | | | | |
| Ampli- | | | | | | |
| tude | | | | | | |
| Phase | 345 | 167 | 108 | 286 | 226 | 45 |
| Angle | | | | | | |
| Phase | 330~30 | 150~210 | 90~150 | 270~330 | 210~270 | 30~90 |
| Range | | | | | | |

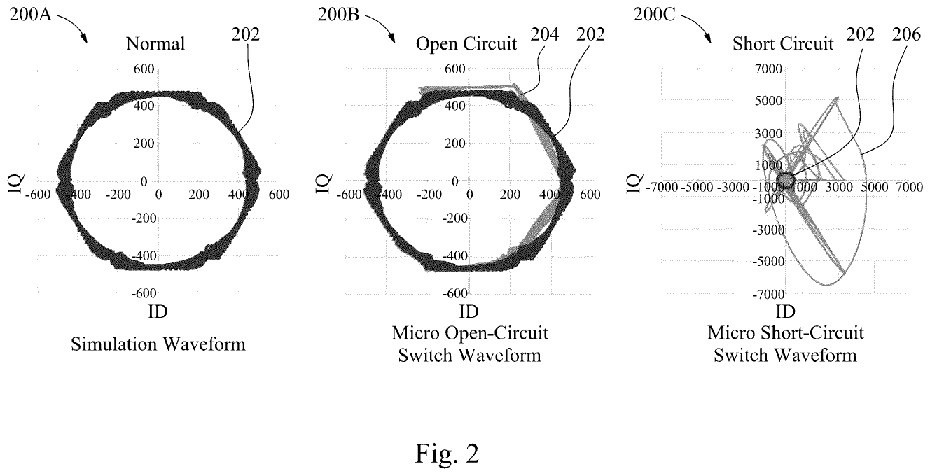

To determine the potential fault, the current controller 110 can generate one or more plots to compare measured and simulated values (e.g., amplitudes at various phase angles). The one or more plots can be generated using the computed amplitudes and phase angles, e.g., based on the simulated current signals and/or the measured current signals. The generation of the one or more plots can be described in conjunction with at least FIG. 2. It should be noted that the example plots are generated as examples, and in some cases, the current controller 110 may perform other techniques (additionally to or alternatively from the example plots) to record or store the computations, such that simulated and measured values can be compared and discrepancies (or inconsistencies/inconsistence) can be identified to determine potential faults.

FIG. 2 illustrates example plots 200A-C of simulated and/or measured amplitudes of current waveforms from the system of FIG. 1, in accordance with some embodiments. The example plots 200A-C are provided as examples to illustrate a potential plotting of the amplitudes computed from the simulated or measured current signals, and are not intended to limit the features or operations discussed herein. The x-axis and γ-axis of the plots 200A-C can represent the two orthogonal components, where each point of the waveforms in the plots 200A-C can represent an amplitude at a corresponding phase angle.

The current controller 110 can generate plot 200A including simulation waveform 202 (e.g., ideal waveform). The simulation waveform 202 can represent the amplitudes and phase angles computed according to current signals from the simulation of the power conversion circuit 101 operating normally, e.g., simulating the current signals under the assumption that the switches are functioning normally. A normally functioning switch can refer to a switch that is not an open circuit or closed circuit, and operating as intended or desired. For example, the current controller 110 can generate plot 200A (e.g., a first plot) based on a vector derived by the example formula/equation (e.g., example formula (1) and/or (2)), a corresponding amplitude and a corresponding phase angle of the vector being calculated through the current signals that are simulated under an assumption that the switches 104 of the power conversion circuit 101 each function normally.

The current controller 110 can generate plot 200B including measured waveform 204. The measured waveform 204 can represent amplitudes and phase angles computed according to measured current signals when at least one of the switches 104 is open. The plot 200B may include the simulation waveform 202 for comparison with the measured waveform 204. For example, the current controller 110 can generate the plot 200B (e.g., a second plot) based on a vector derived by the example formula(s), a corresponding amplitude and a corresponding phase angle of the vector being calculated through the current signals that are measured during operation of the power conversion circuit, e.g., measured current values or signals.

The current controller 110 can generate plot 200C including measured waveform 206. The measured waveform 206 can represent amplitudes and phase angles computed according to measured current signals when at least one of the switches 104 is shorted. The plot 200C can include the simulation waveform 202 for comparison with the measured waveform 206. The generated plots 200A-C are provided as examples, for instance, to illustrate example measurements for at least one switch experiencing an open fault or a short fault. The current controller 110 can store the plot in a memory or storage device of the detection circuit 102. In some cases, the waveforms 202, 204 or waveforms 202, 206 may be generated in separate plots.

In some implementations, the current controller 110 can provide one or more plots 200A-C to an external device. The one or more plots 200A-C can be presented and analyzed by an operator to determine anomalies, abnormalities, or inconsistencies between the measured and simulated waveforms. The inconsistencies can refer to differences between the measured and simulated waveforms. The inconsistencies can represent a potential anomaly associated with at least one of the switches 104, e.g., a potential failure of at least one switch 104 in the power conversion circuit 101. Alignments between the measured and simulated waveforms (e.g., no inconsistencies) can represent no anomalies associated with the switches 104.

In various implementations, the current controller 110 can (automatically) detect inconsistencies or differences between the measured and simulated waveforms. For example, the current controller 110 can compare the amplitudes of the measured and simulated waveforms at various phase angles. The current controller 110 can determine differences between the amplitudes of the measured and simulated waveforms based on the comparison. The current controller 110 can compare the differences to a predetermined threshold. The current controller 110 can detect an inconsistency between the measured and simulated waveforms based on at least one amplitude (at a certain phase angle) being greater than or equal to the predetermined threshold. Based on the detected inconsistency, the current controller 110 can obtain the phase angle associated with the inconsistency and identify the phase range of the phase angle. The identified phase range (e.g., referring to the example Table 1 or example Table 2, depending on the) can represent one of the switches 104. Hence, the current controller 110 can detect one of the switches 104 with a potential fault using the generated plot (e.g., 200B or 200C).

For example, the current controller 110 can compare the amplitudes of the waveforms 202, 204 of plot 200B at various phase angles. The waveform 202 can refer to a first plot (or waveform of the first plot) and the waveform 204 can refer to a second plot (or waveform of the second plot). The current controller 110 can detect an inconsistence between the two waveforms 202, 204 (or between the first and second plots). The inconsistence can occur between the amplitude of the waveform 202 and the amplitude of the waveform 204 at a certain phase angle. For instance, the current controller 110 may detect the inconsistence at a phase angle of approximately 45 degrees based on the difference between the amplitudes of the waveforms 202, 204 being greater than or equal to the predetermined threshold.

In some cases, the current controller 110 may determine whether the amplitude difference represents a potential open circuit or short circuit by comparing the difference to predetermined ranges of difference. If the difference falls within a first range (e.g., relatively low amplitude difference), the current controller 110 can determine that the amplitude difference represents a potential open circuit. If the difference falls within a second range (e.g., relatively high amplitude difference), greater than the first range, the current controller 110 can determine that the amplitude difference represents a potential short circuit.

Using the generated table or mapping (e.g., example Table 1 or example Table 2), the current controller 110 can identify the phase range of the detected inconsistence. For example, the current controller 110 may determine that the inconsistence of the example plot 200B may represent an abnormally open circuit. In such cases, the current controller 110 may use the example Table 1. If the inconsistence appear at approximately 45 degrees phase angle, the current controller 110 can identify T4 as the switch potentially having a fault (e.g., abnormally open). The inconsistence may appear at other phase angles within the phase range for the current controller 110 to identify T4 as the switch, in this case. In other scenarios, the current controller 110 may detect the anomaly or inconsistence at other phase angles.

In another example, the current controller 110 may generate the plot 200C. The current controller 110 can compare the amplitudes of the waveforms 202, 206 of plot 200C at various phase angles, where an anomaly or inconsistence may be detected by comparing the difference between the amplitudes to a predetermined threshold (e.g., closed circuit threshold). The current controller 110 can determine that the difference is greater than the predetermined threshold. In this case, the difference may be within or above the second range of difference which may represent an abnormally short circuit or switch. For instance, in plot 200C, the current controller 110 may detect the inconsistence at a first phase angle of approximately 60 to 70 degrees (for a first switch) and a second phase angle of approximately 300 degrees (for a second switch). For a potential short circuit, the current controller 110 can leverage the example Table 2 (e.g., mapping between individual switches and phase ranges). In this case, the current controller 110 can identify that the first switch associated with 60 to 70 degrees phase angle is T6 and the second switch associated with 300 degrees phase angle is T4.

In further examples, the current controller 110 can differentiate between discrepancies being an open circuit or a closed circuit according to a range of the difference between the amplitudes of the respective waveforms. For instance, inconsistencies within a first range of difference (e.g., relatively smaller difference, but greater than the predetermined threshold) may represent a potential open circuit. In some cases, inconsistencies outside of the first range (or in a second range) of difference (e.g., relatively larger difference) may represent a potential short circuit. The current controller 110 can utilize other suitable techniques to differentiate between the discrepancies being an open circuit or a closed circuit. The current controller 110 can use any other suitable techniques for analyzing and detecting inconsistence in the generated plot, such as at least one of graph analysis, point-by-point comparison, cross correlation, etc. The inconsistence may be identified or detected at other phase angles, not limited to the examples herein.

The current controller 110 can provide an anomaly detection result, notification, or alert to an external device indicating any switch potentially experiencing a fault and the type of fault (e.g., open circuit or short circuit). The current controller 110 can determine one or more actions responsive to detecting the anomaly. The action may include at least one of adjusting the operation of at least one of the switches 104 (e.g., the identified switch), initiating a fault recovery process, or shutting down the power conversion circuit 101 to prevent potential or further damage. In some cases, the action can include sending a report or summary of the analysis responsive to a completion, sending an alert responsive to detecting an anomaly, or provide other indications to an operator device or external device.

In further cases, the action may include terminating operations, actively shutting down, or turning off a device implemented with or including the power conversion circuit 101. The action may be predetermined by the operator or the administrator, and preconfigured for the detection circuit 102. The current controller 110 may determine the one or more actions to take based on at least one of but not limited to the type of anomaly (e.g., open or short circuit), the number of switches experiencing the anomaly, or the particular switch experiencing the anomaly. In some implementations, subsequent to detecting the anomaly, one or more components can be replaced or repair, e.g., the notification can inform an operator to perform a maintenance on one or more components of the system 100.

The current controller 110 can communicate with other components of the detection circuit 102 to execute the action. The current controller 110 can, at least in part, provide a command to control the operation of the one or more switches 104. For example, the current controller 110 can send two orthogonal components (e.g., v_{conq} and v_{cond}) to the transformation circuit 112 indicating the desired voltage amplitude (or magnitude) and the phase angle. The transformation circuit 112 can utilize at least the example formula (2) to convert the orthogonal components to the voltage control signals (e.g., v_{conA}, v_{conB}, and v_{conC}). The transformation circuit 112 can provide the control signals to the PWM circuit 114. The voltage control signals can control one or more of the switches 104 for phases A, B, and C, respectively.

The PWM circuit 114 can receive the control voltages v_{conA}, v_{conB}, and v_{conC} from the transformation circuit 112. The PWM circuit 114 can use the control voltages to generate PWM signals (e.g., S1-S6) that control the switching of the switches 104 of the power conversion circuit 101. The PWM circuit 114 can adjust the duty cycle (or other operations) of the PWM signals based on the control voltages to achieve the desired action, e.g., desired output current, voltage, phase, etc. For example, if an open circuit anomaly is detected, the PWM circuit 114 can modify the PWM signals to reduce the stress on the affected switch, e.g., reducing voltage or frequency. If a short circuit anomaly is detected, the PWM circuit 114 can adjust the PWM signals to prevent further damage to the circuit, e.g., terminate actions of the one or more switches 104. The PWM circuit 114 can transmit the generated PWM signals to the drive circuit 116.

The drive circuit 116 can receive the PWM signals from the PWM circuit 114. The drive circuit 116 can use these signals to control the gate drivers of the switches T1-T6 in the power conversion circuit 101. For instance, the drive circuit 116 may operate as an interface unit for controlling or communicating with one or more components of the power conversion circuit 101. In some cases, the drive circuit 116 may be electrically coupled to the gate terminals of individual switches 104 to control the switching operation. The drive circuit 116 can operate the switches according to the PWM signals, including implementing the corrective actions determined by the current controller 110. For example, the drive circuit 116 can turn off a switch experiencing a short circuit to prevent further damage or adjust the switching frequency to mitigate the effects of an open circuit. The drive circuit 116 may provide feedback to the current controller 110 on the status of the switches 104, for example. In certain configurations, the predetermined action may involve terminating the operations of all switches 104 in response to detecting the anomaly, such that the operator can initiate a maintenance procedure.

The detection circuit 102 can include other components to perform other features or functionalities. For example, the detection circuit 102 can include the interface circuit 118, the transformation circuit 120, and the voltage controller 122. The interface circuit 118 can receive voltage signals (e.g., voltage data or values) measured or simulated in the power conversion circuit 101. The voltage signals (e.g., V_{ab}, V_{bc}, and v_{ca}) can be associated with the three-phase system where the first voltage signal (e.g., V_{ab}) can be captured between nodes a and b downstream from the inductors L, the second voltage signal (e.g., V_{bc}) can be captured between nodes b and c downstream from the inductors L, and the third voltage signal (e.g., v_{ca}) can be captured between nodes a and c downstream from the inductors L. In some implementations, the voltage signals may be utilized in conjunction with the current signals discussed herein, e.g., to detect potential faults in at least one of the switches 104 of the power conversion circuit 101. In some other cases, the voltage signals can be utilized for other purposes. The transformation circuit 120 can process the voltage signals for the voltage controller 122. Processing the voltage signals can include obtaining one or more orthogonal components, among other derivatives of the voltage values. The voltage controller 122 can utilize the processed voltage values to regulate the output voltage of the power conversion circuit 101. The regulation can involve, but is not limited to at least one of maintaining the output voltage within a specified range, compensating for voltage fluctuations, or ensuring stable operation of the system, for example.

The voltage controller 122 can generate control signals based on the processed voltage values to achieve the desired voltage regulation. These control signals can be sent to components such as the PWM circuit 114, the drive circuit 116, or in some cases, to the current controller 110 to send the control signals to the PWM circuit 114 or the drive circuit 116. The PWM circuit 114 can adjust the duty cycle of the PWM signals to regulate the output voltage. The drive circuit 116 can manage the gate drivers of the switches T1-T6 to implement the adjustments. Other types of command can be generated and signaled to the PWM circuit 114 or the drive circuit 116.

The detection circuit 102 can include a memory unit that stores the simulated values, measured values, signals, generated plots, generated tables, or other information received, obtained, or otherwise generated by the detection circuit 102 or the power conversion circuit 101. The memory unit can provide storage for the data used in the fault detection process. The memory unit can store one or more actions to execute when an anomaly is identified. The memory unit can store a time interval for when to execute the analysis. The stored data can be accessed by the one or more components of the detection circuit 102 (or by other authorized drives or circuits) for analysis and comparison. The memory unit can store the results of the fault detection process, including the identified faults and the corresponding switches.

The detection circuit 102 can communicate with external systems or devices to report the detected faults. This communication can be achieved through various interfaces, such as wired or wireless communication channels. The detection circuit 102 can send alerts or notifications to external systems, indicating the presence of a fault and the specific switch that is causing or may cause potential problem related to the operation or health of the power conversion circuit 101. The communication can be a part of the corrective actions to address the detected faults.

The detection circuit 102 can be designed to operate in real-time, continuously monitoring the operation of the power conversion circuit 101. The real-time monitoring can enable the detection circuit 102 to responsively identify and report any faults, ensuring the reliability and efficiency of the power conversion circuit 101. In some cases, one or more components of the detection circuit 102 may operate at predefined intervals for detecting potential faults. The detection circuit 102 can use various analysis techniques, such as the current analysis, temperature analysis, and/or voltage spectrum analysis, to detect faults in the switches 104. The detection circuit 102 can be utilized for other circuits, not limited to the power conversion circuit 101 for detecting faults.

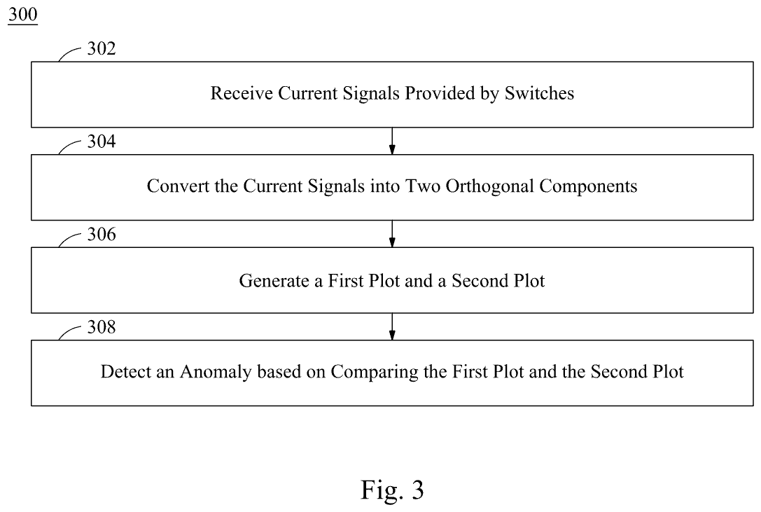

FIG. 3 illustrates an example flow chart of a method 300 for detecting failure of the semiconductor devices, in accordance with some embodiments. The method 300 can be performed by one or more circuits or devices of at least the system 100, as described in conjunction with FIG. 1. For example, one or more operations of the method 300 may be executed by the detection circuit 102 for detecting a potential failure, fault, or anomaly of the IGBT (or switch) implemented in the power conversion circuit 101. Accordingly, the following discussion of the method 300 may refer to some of the reference numerals used in at least one of FIGS. 1-2 as a non-limiting example. Further, the method 300 is merely an example, and is not intended to limit the present disclosure. It should thus be understood that additional operations may be provided before, during, and after the method 300 of FIG. 3, and that some other operations may only be briefly described herein. The method 300 can be performed simultaneously and/or in any order other than the order depicted in FIG. 3.

The method 300 can start with operation 302 of receiving (or retrieving) current signals provided by a plurality of switches (e.g., switches 104, e.g., IGBTs). One or more components of the detection circuit (e.g., 102), such as an interface circuit (e.g., 106) can receive or retrieve a first current signal (I_{Uav}), a second current signal (I_{Vav}), and a third current signal (I_{Wav}) from a power conversion circuit (e.g., 101). The detection circuit can be operatively coupled to the power conversion circuit. The power conversion circuit can include a plurality of switches (e.g., 104). Each of the switches can have three terminals, including a gate terminal, a first S/D terminal, and a second S/D terminal, for example. The operations of method 300 can be performed or executed by at least the detection circuit.

The first current signal can be provided by a first pair of the switches, e.g., T1 and T2. The second current signal can be provided by a second pair of switches, e.g., T3 and T4. The third current signal can be provided by a third pair of switches, e.g., T5 and T6. The first pair of switches can include a first switch (e.g., T1 or 104A) and a second switch (e.g., T2 or 104B) operatively forming a first phase leg. The first leg can be connected to node A in the power conversion circuit, such as described in conjunction with at least FIG. 1. The second pair of switches can include a third switch (e.g., T3 or 104C) and a fourth switch (e.g., T4 or 104D) operatively forming a second phase leg. The second leg can be connected to node B in the power conversion circuit. The third pair of switches can include a fifth switch (e.g., T5 or 104E) and a sixth switch (e.g., T6 or 104F) operatively forming a third phase leg. The third leg can be connected to node C in the power conversion circuit. Individual switches discussed herein may include or be implemented with insulated gate bipolar transistors (IGBTs). In some cases, the switches may be implemented with other semiconductor devices or other types of transistors.

The current signals (e.g., the first to third current signals) can include measured signals captured by one or more sensors. The interface circuit can receive the sensor data corresponding to the current signals or values. In some cases, the current signals can include simulated signals from a simulation conducted for the configuration of the power conversion circuit. The simulation can involve simulating the current signals for the power conversion circuit with all the switches operating as intended or normal. In some cases, the simulation can involve simulating the current signals for the power conversion circuit with individual switches being in an open state or a shorted state for a relatively brief timeframe.

The method 300 can continue to operation 304 of converting the current signals into two orthogonal components. The one or more components of the detection circuit (e.g., the transformation circuit 108) can convert the first to third current signals into two orthogonal components. The transformation circuit can perform the conversion using a formula or equation. For example, a first one (I_{Dav}) of the two orthogonal components can be represented as or derived from:

$${I}_{Dav} = \frac{√ 2}{√ 3} {I}_{Uav} - \frac{1}{√ 6} {I}_{Vav} - \frac{1}{√ 6} {I}_{Wav} .$$

A second one (I_{Qav}) of the two orthogonal components can be represented as or derived from:

$${I}_{Qav} = \frac{1}{√ 2} {I}_{Vav} - \frac{1}{\sqrt{2}} {I}_{Uav} + {I}_{Q0} .$$

The method 300 can then proceed to operation 306 of generating a first plot and a second plot. The one or more components of the detection circuit (e.g., current controller 110) can generate a first plot and a second plot, each based on the two orthogonal components or the vector derived from the two orthogonal components. The vector derived from the two orthogonal components can be derived using a formula. For example, the current controller can generate a vector having an amplitude (I_{Sav}) and a phase angle (∠θ_{Sav}) based on following equation:

$${I}_{Sav} = \sqrt{{1}_{Dav}^{2} + {I}_{Qav}^{2}} , {∠θ}_{Sav} = arctan \frac{{I}_{Qav}}{{I}_{Dav}} .$$

The amplitude and the phase angle can represent one of a plurality of vectors to generate a respective plot.

The plot may include or correspond to a waveform formed from the vectors generated based on the two orthogonal components. The current controller can generate the first plot (e.g., 200A or waveform 202) based on a first vector derived by the equation, where a corresponding first amplitude and a corresponding first phase angle of the first vector may be calculated through the first to third signals that are simulated under an assumption that the switches of the power conversion circuit each function normally. For instance, the first plot can represent a vector or values expected when measuring the power conversion circuit under normal operation conditions.

The current controller can generate the second plot (e.g., 200B or 200C or waveform 204 or waveform 206) based on a second vector derived by the equation, where a corresponding second amplitude and a corresponding second phase angle of the second vector may be calculated through the first to third signals that are measured during operation of the power conversion circuit. In this case, the first plot can represent a vector or values measured by the one or more sensors of the power conversion circuit during the operations of the switches.

The method 300 can continue to operation 308 of detecting an anomaly based on comparing the first plot and the second plot. The one or more components of the detection circuit (e.g., current controller 110) can detect an anomaly associated with at least one of the switches based on comparing the first plot and the second plot, e.g., comparing between simulation and measured waveforms. The current controller can determine the anomaly in response to identifying an inconsistence between the first plot and the second plot. The inconsistence can refer to a difference that occurs between the first amplitude of the first plot and the second amplitude of the second plot at a certain phase angle, for example. For the difference to be considered an inconsistence or an anomaly, the difference may be greater than or equal to a predetermined threshold or range.

In some cases, based on the identified inconsistence, the current controller can determine that the anomaly results from one of the switches being abnormally open (e.g., at least one switch under an open circuit condition). The inconsistence can occur between the first phase angle and the second phase angle. In some other cases, based on the identified inconsistence, the current controller may determine that the anomaly results from one of the switches being abnormally short (e.g., at least one switch under a short-circuit condition).

In some cases, the detection circuit (e.g., current controller) can identify one of the switches as an open circuit based on a relatively smaller offset between the amplitudes of the plots. For example, if the inconsistency or offset falls within a first range of difference (e.g., representing a relatively small offset), the current controller can determine that the switch may be experiencing an open circuit condition. The relatively small offset can indicate a relatively small deviation of the measured amplitude from the expected amplitude of switches operating under a normal condition. Such deviation may indicate that the switch is not conducting current normally.

In some cases, the current controller may identify one of the switches as a short circuit based on a relatively larger offset between the amplitudes of the plots. For example, if the inconsistency or offset is above the first range of difference or falls within a second range of difference that is greater than the first range (e.g., representing a relatively large offset, such as two or three times greater than an offset for the open circuit condition), the current controller can determine that the switch may be experiencing a short circuit condition. The relatively large offset can indicate a relatively large deviation of the measured amplitude from the expected amplitude when the switch is operating under a normal condition. Such deviation may indicate that the switch is conducting current when it is not supposed to, potentially causing or indicating a short circuit. The detection circuit can utilize or perform other techniques, for instance, to differentiate between at least one of the switches experiencing an open circuit condition or a short circuit condition.

Subsequent to identifying the anomaly, one or more components of the detection circuit (e.g., a drive circuit 116) can adjust one or more of a plurality of control signals gating the first to third pairs of switches, respectively, based on the identified anomaly. For example, the drive circuit may turn off or deactivate the switch (or associated pair of switches) identified to potentially have the anomaly. The drive circuit may adjust the switching frequency of the at least one switch associated with the anomaly. The drive circuit can perform other actions to control the one or more switches. The controls of the drive circuit can be predetermined or pre-configured. The drive circuit can control the one or more switches based on the type of anomaly or fault and/or the number of switches having the anomaly, for example. In some implementations, the detection circuit may provide a report including results from the analysis to an external device (e.g., an operator device). In some configurations, in response to detecting an open circuit or short circuit associated with one of the switches, the detection circuit may deactivate or terminate the operation of the power conversion circuit and notify the operator to initiate a maintenance procedure. Other actions to prevent further damage to the system or circuit can be executed, not limited to those discussed herein.

### Example Implementation for Temperature Method

Based on the current signals flowing through each of the switches T1 to T6, a total power (Pₗₒₛₛ) can be calculated based on the following formula/equation (3):

$${P}_{loss} = {P}_{SW} + \frac{{R}_{ce} {I}_{c}^{2}}{8} ( 1 + \frac{8 \times m cos ( φ )}{3 π} - \frac{8 \sqrt{3} \times m cos ( 3 φ )}{40 {π}^{2}} + \frac{{V}_{ceo} {I}_{c}}{2 π} ( 1 + \frac{2 π \times m cos φ}{8} ) . \qquad ( 3 )$$

In the example formula (3), the P_{SW} can represent or denote a switching power of each of the switches T1 to T6. The second and third terms of the example formula (3) can collectively represent a conduction loss of each of the switches T1 to T6. Further, R_{ce} can represent an equivalent resistance of each of the switches T1 to T6. The I_{c} can represent the current signal flowing through each of the switches T1 to T6. The φ can represent a phase of each of the switches T1 to T6. V_{ceo} can represent a threshold voltage of each of the switches T1 to T6.

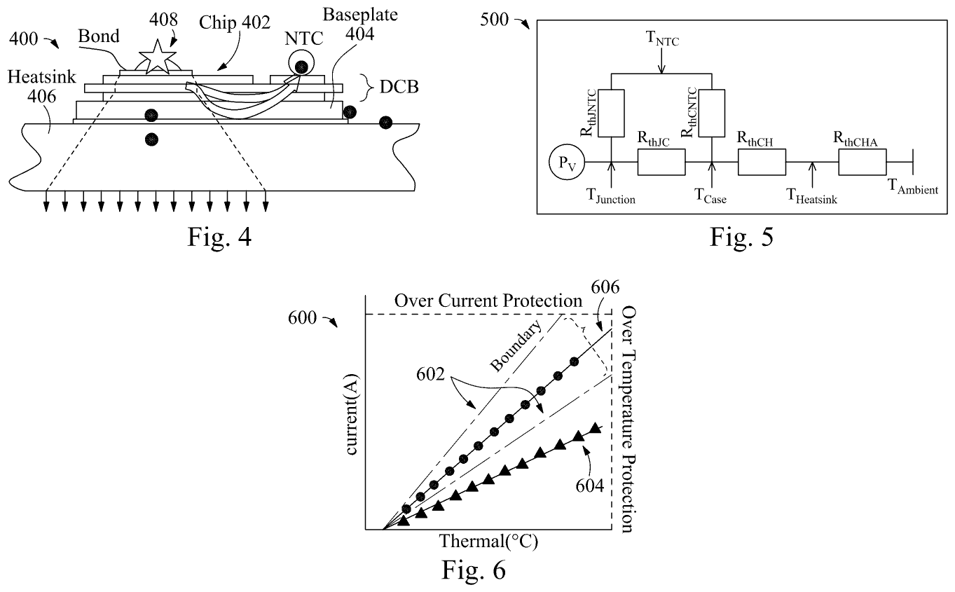

In some configurations, in addition or alternative to the current analysis, technique, or method as discussed hereinabove, the detection circuit 102 can rely on the total power (Pₗₒₛₛ) and a measured temperature (T_{NTC}) to determine or estimate a junction temperature (T_{junction}). Based on the estimated junction temperature, the detection circuit 102 can determine whether any of the switches T1 to T6 may tend to malfunction or have malfunctioned. For example, FIG. 4 illustrates an example structure 400 including the power conversion circuit 101 (embodied as a chip 402) bonded to a heatsink 406, in accordance with some embodiments. FIG. 5 illustrates a block diagram of a thermal model 500 of the structure 400 described in conjunction with at least FIG. 4, in accordance with some embodiments.

In FIG. 4, the heatsink 406 can be formed as the bottommost layer, providing thermal management by dissipating heat away from the components or materials above. The heatsink can be coupled to a baseplate 404 of a component, e.g., a baseplate of the system 100 of FIG. 1, including the power conversion circuit 101 (embodied as the chip 402). The baseplate 404 can serve as a mechanical support, aiding in heat dissipation. The baseplate 404 can be fabricated or positioned above the heatsink 406. One or more direct copper bonded (DCB) layers can be formed or fabricated above the baseplate 404. The DCB layers can include a ceramic substrate with copper bonded on both sides, for example. The DCB layers can provide electrical insulation and thermal conductivity, for instance, between at least the chip 402 and the baseplate 404. The chip 402 and a negative temperature coefficient (NTC) thermistor can be formed above the DCB layers. The chip 402, including or corresponding to the power conversion circuit 101, can correspond to a semiconductor device, including at least IGBTs, for example. The chip 402 and/or the NTC can be bonded to the heatsink 406 through the baseplate 404 and DCB layers using at least one suitable bonding technique, such as soldering, applying adhesive materials, etc. The NTC thermistor can be positioned adjacent to the chip 402. The NTC thermistor can monitor the temperature of the chip 402 or of the surroundings of the chip 402. The NTC thermistor can provide feedback including thermal data for thermal management, for instance, at least to the detection circuit 102 or other circuits authorized to receive the thermal data for analysis. Although not shown in FIG. 4, the detection circuit 102 can be electrically or communicatively coupled to the chip 402 (e.g., the power conversion circuit 101) to perform the analysis using temperature data.

The junction temperature may refer to or be represented by the star symbol (e.g., 408) shown in FIG. 4. The junction temperature can reflect a true temperature while operating the power conversion circuit 101. The measured temperature may refer to a temperature that is measurable through any suitable method, such as via at least one temperature sensor, among other types of sensors or measurements. During the operation of the power conversion circuit 101, the detection circuit 102 can calculate the total power (which corresponds to Pᵥ in FIG. 5), and with a set of data corresponding to the measured temperature retrieved, the power conversion circuit 101 can estimate the junction temperature based on the thermal model shown in FIG. 5. For instance, in FIG. 5, multiple thermal resistance values (R_{thJNTC}, R_{thJC}, R_{thHA}) can be modeled or otherwise provided based on various experimental or measured data (T_{case}, T_{Heatsink}, T_{Ambient}).

Based on this principle and various experimental or measured data, a tolerable boundary, defining a relationship between the junction temperature and the current signal (e.g., current values) flowing through at least one of the switches 104, can be set/configured, such as shown FIG. 6. Accordingly, with the power conversion circuit 101 being in operation, the detection circuit 102 can real-time monitor a relationship (or plot) between the current signal and the junction temperature, and determine whether the plot is enclosed by or within the boundary. The plot can include, correspond to, or be represented by data points or vectors. If the plot is enclosed by (or within) the boundary, the detection circuit 102 can determine that a particular switch does not tend to malfunction. On the other hand, if the plot is outside the boundary, the detection circuit 102 can determine that a particular switch tends to malfunction.

For example, FIG. 6 illustrates an example graph 600 indicating the relationship between the current signal and the junction temperature for one or more switches (e.g., one or more of T1 to T6) of the power conversion circuit 101 associated with the example structure of FIG. 4, in accordance with some embodiment. The graph 600 can include one or more boundaries 602 indicative of the acceptable range of operation for the switches. The boundary 602 can be established based on at least the principle and/or the experimental or measured data discussed hereinabove.

Within the boundaries (or acceptable range), at least one of the switches 104 can be expected to operate reliably without any malfunctions. Outside the boundaries, at least one of the switches 104 may be considered as tending to malfunction or malfunctioning. The graph 600 can display real-time data points 604, 606, each data point can represent the current signal and junction temperature for at least one respective switch. For purposes of providing examples, the data points 604 can be associated with one of the switches 104 and the data points 606 can be associated with another one of the switches 104. For example, the data points 606 may fall within the boundary 602. The detection circuit 102 can determine that the corresponding switch of the data points 606 is operating normally. The detection circuit 102 may identify the data points 604 as falling outside the boundary 602. In such cases, the detection circuit 102 can identify the switch associated with the data points 604 as potentially malfunctioning or tending to malfunction.

The detection circuit 102 can use at least the plot 600 to monitor the performance of the switches 104 within the power conversion circuit 101 (or other circuits or devices). By analyzing the position of the data points 604, 606 relative to the boundary 602, the detection circuit 102 can detect early signs of potential faults associated with at least one of the switches 104. For instance, if a data point 604 gradually moves towards the edge of the boundary 602, the detection circuit 102 may interpret such an indication as the respective switch experiencing stress may potentially fail. The detection circuit 102 can take proactive measures, such as adjusting the operating conditions or scheduling maintenance, to prevent a complete failure of the component or the system. This real-time monitoring and analysis can ensure the reliability and efficiency of the power conversion circuit 101, minimizing downtime and extending the lifespan of the switches 104.

### Example Implementation for Voltage Spectrum Method

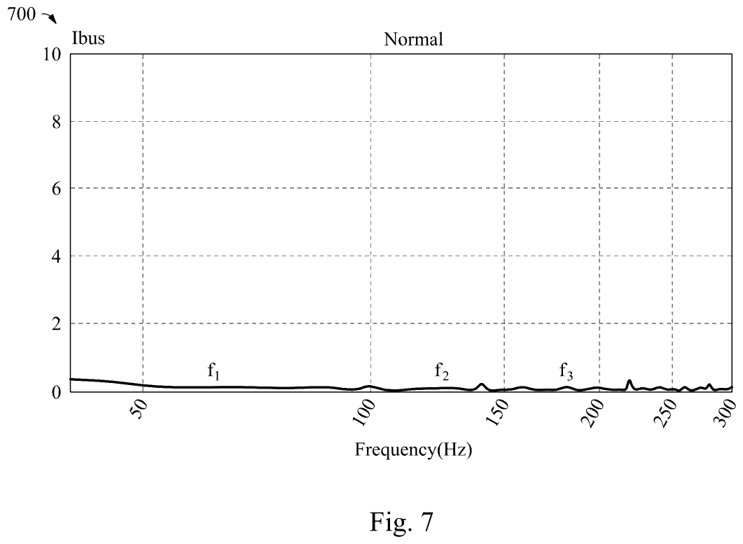

In some configurations, additionally or alternatively to the current analysis and/or the temperature analysis discussed hereinabove, the detection circuit 102 can rely on voltage spectrums (or frequency response graphs) based on a Bode plot to determine whether any of the switches T1 to T6 may tend to malfunction or have malfunctioned. FIGS. 7-10 illustrate Bode plots 700-1000 for analyzing the health status of one or more switches 104 (e.g., IGBTs) in the power conversion circuit 101 of the example system 100 described in conjunction with at least FIG. 1, in accordance with some embodiments. The plots 700-1000 can be utilized by at least the detection circuit 102 (or the one or more components of the detection circuit 102) to detect potential faults in the power conversion circuit 101.

Each of the plots 700-1000 can be a graphical representation of a frequency response of a system (e.g., the power conversion circuit 101), showing changes in the magnitude and phase of a signal with respect to frequency. The plots 700-1000 may be referred to as frequency response graphs, including voltage spectrums for analysis by at least the detection circuit 102.

For example, the detection circuit 102 can store a first Bode plot 700 (e.g., shown in FIG. 7), with assurance that all of the switches T1 to T6 function normally. In other words, the first Bode plot 700 can represent the frequency response when the switches 104 of the power conversion circuit 101 are operating normally (with no malfunction). As shown, when all the switches T1 to T6 function normally, there may not be a spike in any of the major frequencies f₁, f₂, and f₃ (corresponding to the 1^{st}, 2^{nd}, and 3^{rd} harmonic orders, respectively).

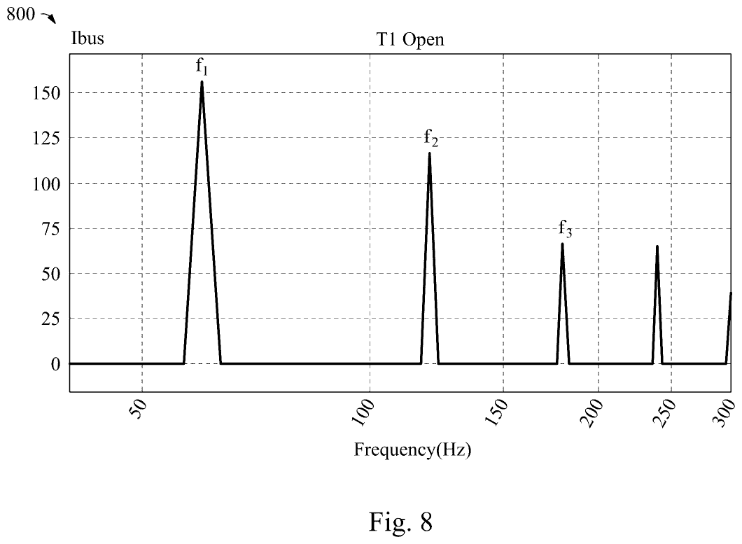

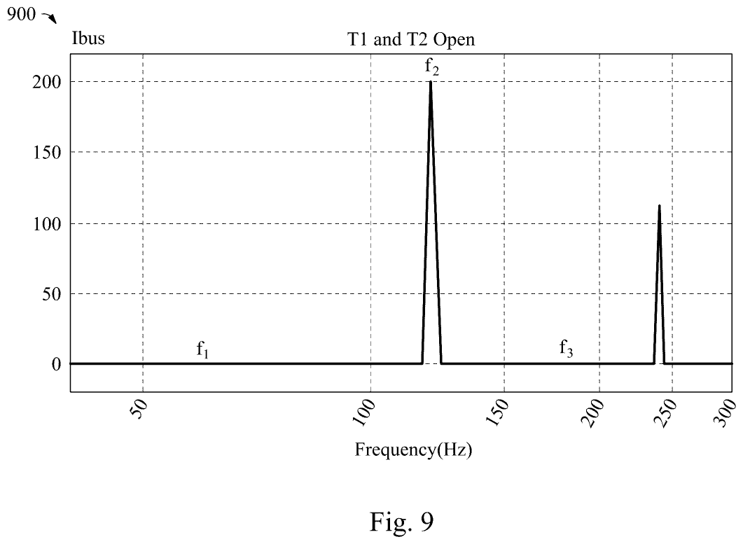

In certain scenarios, a second Bode plot 800 (e.g., FIG. 8) may include spikes at the first to third harmonic frequencies f₁, f₂, and f₃. In response to detecting the spikes at the first to third harmonic frequencies, the detection circuit 102 can determine that switch T1 may be experiencing an open circuit condition. In another scenario, a third Bode plot 900 (e.g., FIG. 9) may include a spike at the second harmonic frequency f₂. In such cases, the detection circuit 102 can determine that switches T1 and T2 may be experiencing open circuit conditions based on the spike detected at the second harmonic frequency f₂.

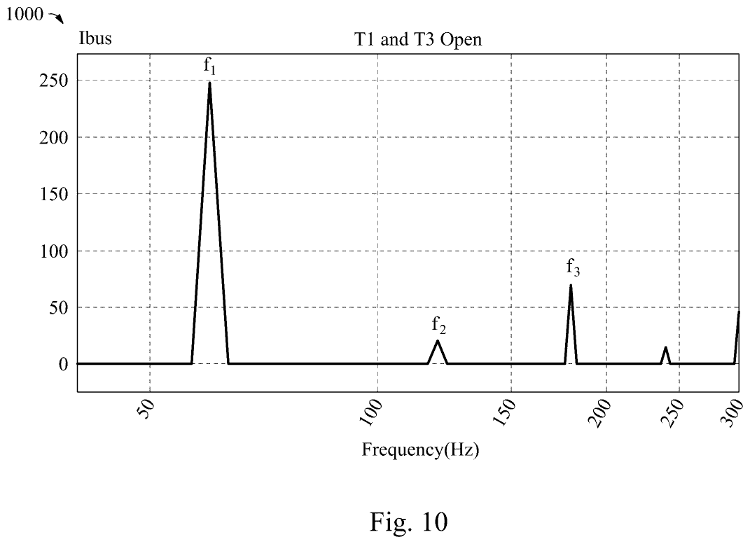

In yet another scenario, a fourth Bode plot 1000 (e.g., FIG. 10) may include spikes at the first and third harmonic frequencies, e.g., f₁ and f₃. In response to detecting the spikes at these harmonic frequencies, the detection circuit 102 can determine that switches T1 and T3 may be experiencing the open circuit condition. The detection circuit 102 may detect a spike based on the magnitude (or change in magnitude) in a plot being greater than or equal to a predetermined threshold. The threshold can be modified or configured by the operator of the system 100. The predetermined threshold may be different depending on the configuration of the power conversion circuit 101 or the specification of the switches 104. For purposes of providing examples, example magnitudes at the first to third harmonic frequencies during different conditions of the one or more switches 104 can be included in the example Table 3.

Example Table 3

| | | | Third |
|---|---|---|---|
| | First Harmonic | Second Harmonic | Harmonic |
| Normal | 0.092 | 0.063 | 0.095 |
| T1 Open | 156.226 | 116.315 | 66.39 |
| T1 and T2 Open | 0.0348 | 199.636 | 0.01 |
| T1 and T3 Open | 248.108 | 21.3543 | 69.729 |

In some cases, the detection circuit 102 may deploy a graph analysis technique (or other types of analysis techniques) to detect one or more spikes at the harmonic frequencies in the plots 800-1000. In some implementations, one or more Bode plots (e.g., 700-1000) may include more than three harmonic frequencies (or in some cases less than three harmonic frequencies). In some configurations, at least one of the different harmonic frequencies having the spikes or the magnitude of the respective spikes can be configured or predefined to represent at least one switch 104 experiencing a malfunction or fault and/or the type of malfunction associated with the at least one switch 104.

In some cases, the detection circuit 102 may determine which of the switches 104 may be experiencing the open circuit condition or the short circuit condition according to the pattern of the one or more spikes within the Bode plots 700-1000. The spike pattern may be predetermined or simulated and stored in the memory. The detection circuit 102 can utilize other analysis or historical data to detect at least one of the switches 104 potentially experiencing the fault condition or the type of fault experienced by at least one of the switches 104. It should be noted that the plots 700-1000 are provided as examples and are not intended to limit the other possible implementations or variations that may be made without departing from at least the features or functionalities herein.

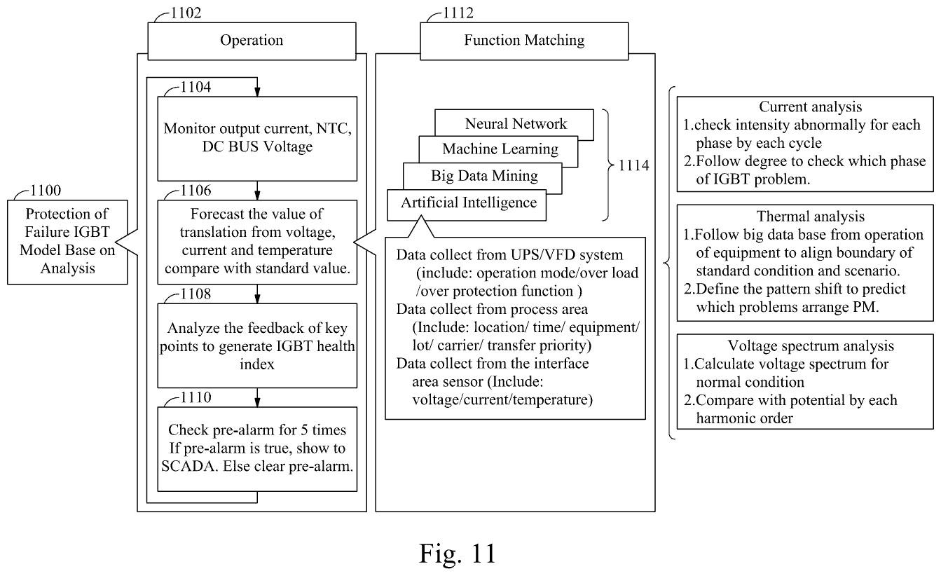

FIG. 11 illustrates an overview 1100 of analysis techniques executed by the example system 100 of FIG. 1 for detecting failure of semiconductor devices, in accordance with some embodiments. The operations of FIG. 11 can be executed or performed by one or more components of the example system 100, such as the power conversion circuit 101 and the detection circuit 102 described in conjunction with at least FIG. 1. For example, the one or more components (e.g., interface circuit 106, transformation circuit 108, current controller 110, drive circuit 116, etc.) of the detection circuit 102 can execute various operations discussed herein for protecting failure of IGBT model based on at least one analysis technique (e.g., current analysis, thermal or temperature analysis, and/or voltage spectrum analysis), at step 1100.

The step 1100 for protecting the failure IGBT (e.g., at least one switch 104) model can involve operation 1102. The operation 1102 can include monitoring the output current, NTC thermistor readings, and (e.g., DC) bus voltage, e.g., at 1104. The detection circuit 102 can collect data for analysis of the health of the IGBT (e.g., switches 104 of the power conversion circuit 101).

At step 1106, the detection circuit 102 can forecast the values of translation from voltage, current, and/or temperature and compare the values with standard values (e.g., values representing normal operation of the switches 104). The translation from the voltage, current, and/or temperature can refer to the values or data obtained during the voltage spectrum analysis, current analysis, and/or the temperature analysis, for example. If the forecasted values deviate significantly from the standard values, the detection circuit 102 can identify or flag the IGBT as potentially malfunctioning.

At step 1106, the detection circuit 102 can forecast the values of voltage, current, and temperature and compare them with standard values. This step involves using predictive algorithms to estimate the future values of these parameters based on historical data and current operating conditions. The forecasted values can be compared with predefined standard values to identify any potential issues. If the forecasted values deviate significantly from the standard values, the detection circuit 102 can flag the IGBT as potentially malfunctioning.

The step 1106 can involve function matching 1112, including techniques 1114 such as neural networks, machine learning, big data mining, and/or artificial intelligence (AI) for data processing. It should be noted that the detection circuit 102 can utilize any suitable data processing technique, machine learning models, or AI algorithms for processing inputs to generate an output (e.g., whether at least one of the switches 104 is potentially experiencing any malfunction such as an open circuit condition or a short circuit condition). These techniques can be used to enhance the accuracy and reliability of the analysis. Data can be collected from various sources, including at least one of the UPS/VFD system (e.g., operation mode, overload, or over-protection function), process area (e.g., location, time, equipment, lot, carrier, or transfer priority), or interface area sensors (e.g., voltage, current, or temperature), to name a few. The comprehensive data collection approach can ensure that the detection circuit 102 has access to all desired information for accurate analysis. The detection circuit 102 can utilize the data for various types of analysis, including but not limited to current analysis, thermal analysis, and/or voltage spectrum analysis discussed herein.

For example, the current analysis can involve at least checking for intensity abnormalities in each phase during each cycle, and following the degree of abnormality to identify which phase of the IGBT (e.g., switch) has a problem. In another example, the thermal or temperature analysis can involve at least using a (big) database from the operation of equipment to align the boundary of standard conditions and scenarios and defining pattern shifts to predict potential problems and arrange preventive maintenance. In further examples, the voltage spectrum analysis can involve at least calculating the voltage spectrum for normal operating conditions and comparing the calculated spectrum with potential deviations at each harmonic order. The detected anomaly can be an indicator for potential malfunctioning of at least one of the IGBTs, e.g., one of the switches 104 in the power conversion circuit 101.

At step 1108, the detection circuit 102 can analyze the feedback from key points to generate an IGBT health index. For example, based on the analysis using at least one of the analysis techniques (e.g., analysis of the current, temperature, or voltage data), the detection circuit 102 can compute the health index representing the overall condition of the IGBTs within the system.

At step 1110, the detection circuit 102 can check for pre-alarms multiple times (e.g., five times). If the pre-alarm condition is met/satisfied, the detection circuit 102 can display an alarm, provide a notification, or otherwise send an alert to a remote device or external system, such as a supervisory control and data acquisition (SCADA) system. Otherwise, the pre-alarm can be cleared. The detection circuit 102 can perform the check to ensure that any potential issues are flagged and addressed promptly to prevent further damage. Further, the check can reduce false positive.

The detection circuit 102 can repeat the operation 1102, e.g., from steps 1104 to 1110. The detection circuit 102 can repeat the operation 1102 at a predetermined time interval, in response to a trigger from an operator, or continuously. The monitoring and analysis of the data can be performed in real-time to provide timely interventions and maintenance to ensure the reliable operation of the power conversion circuit 101, among other systems not limited to the power conversion circuit 101.

In one aspect of the present disclosure, an apparatus is disclosed. The apparatus comprises a power conversion circuit including a plurality of switches, each of the plurality of switches having three terminals; and a detection circuit operatively coupled to the power conversion circuit and configured to: retrieve a first current signal (I_{Uav}), a second current signal (I_{Vav}), and a third current signal (I_{Wav}), wherein the first current signal is provided by a first pair of the plurality of switches, the second current signal is provided by a second pair of the plurality of switches, and the third current signal is provided by a third pair of the plurality of switches; convert the first to third current signals into two orthogonal components; generate a first plot and a second plot each based on the two orthogonal components; and detect an anomaly associated with at least one of the plurality of switches based on comparing the first plot and the second plot.

In another aspect of the present disclosure, a detection circuit is disclosed. The detection circuit comprises an interface circuit configured to receive a first current signal (I_{Uav}), a second current signal (I_{Vav}), and a third current signal (I_{Wav}), wherein the first current signal is provided by a first pair of switches coupled to a supply voltage, the second current signal is provided by a second pair of switches coupled to the supply voltage, and the third current signal is provided by a third pair of switches coupled to the supply voltage; a transformation circuit configured to: (i) convert the first to third current signals into two orthogonal components; (ii) generate a first plot and a second plot each based on the two orthogonal components; and (iii) identify an anomaly associated with at least one of the first to third pairs of switches based on comparing the first plot and the second plot; and a drive circuit configured to adjust one or more of a plurality of control signals gating the first to third pairs of switches, respectively, based on the identified anomaly.

In yet another aspect of the present disclosure, a method for detecting failure of semiconductor devices is disclosed. The method includes receiving a first current signal (I_{Uav}), a second current signal (I_{Vav}), and a third current signal (I_{Wav}), wherein the first current signal is provided by a first pair of switches coupled to a supply voltage, the second current signal is provided by a second pair of switches coupled to the supply voltage, and the third current signal is provided by a third pair of switches coupled to the supply voltage; converting the first to third current signals into two orthogonal components; generating a first plot and a second plot each based on the two orthogonal components; identifying an anomaly associated with at least one of the first to third pairs of switches based on comparing the first plot and the second plot; and adjusting one or more of a plurality of control signals gating the first to third pairs of switches, respectively, based on the identified anomaly.

As used herein, the terms “about” and “approximately” generally indicates the value of a given quantity that can vary based on a particular technology node associated with the subject semiconductor device. Based on the particular technology node, the term “about” can indicate a value of a given quantity that varies within, for example, 10-30% of the value (e.g., +10%, ±20%, or ±30% of the value).

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An apparatus, comprising:
a power conversion circuit including a plurality of switches, each of the plurality of switches having three terminals; and
a detection circuit operatively coupled to the power conversion circuit and configured to:
retrieve a first current signal (I_{Uav}), a second current signal (I_{Vav}), and a third current signal (I_{Wav}), wherein the first current signal is provided by a first pair of the plurality of switches, the second current signal is provided by a second pair of the plurality of switches, and the third current signal is provided by a third pair of the plurality of switches;
convert the first to third current signals into two orthogonal components;
generate a first plot and a second plot each based on the two orthogonal components; and
detect an anomaly associated with at least one of the plurality of switches based on comparing the first plot and the second plot.

2. The apparatus of claim 1, wherein the first pair of the plurality of switches includes a first switch and a second switch operatively forming a first phase leg, the second pair of the plurality of switches includes a third switch and a fourth switch operatively forming a second phase leg, and the third pair of the plurality of switches includes a fifth switch and a sixth switch operatively forming a third phase leg.

3. The apparatus of claim 1,
wherein a first one (I_{Dav}) of the two orthogonal components is represented as:
$${I}_{Dav} = \frac{√ 2}{√ 3} {I}_{Uav} - \frac{1}{√ 6} {I}_{Vav} - \frac{1}{√ 6} {I}_{Wav} ;$$
and
wherein a second one (I_{Qav}) of the two orthogonal components is represented as:
$${I}_{Qav} = \frac{1}{√ 2} {I}_{Vav} - \frac{1}{\sqrt{2}} {I}_{Uav} + {I}_{Q 0} .$$

4. The apparatus of claim 3, wherein the detection circuit is further configured to generate a vector having an amplitude (I_{Sav}) and a phase angle (2θ_{Sav}) based on following equation:
$${I}_{Sav} = \sqrt{{1}_{Dav}^{2} + {I}_{Qav}^{2}} , {∠θ}_{Sav} = arctan \frac{{I}_{Qav}}{{I}_{Dav}} .$$

5. The apparatus of claim 4, wherein the detection circuit is further configured to generate the first plot based on a first vector derived by the equation, a corresponding first amplitude and a corresponding first phase angle of the first vector being calculated through the first to third signals that are simulated under an assumption that the plurality of switches of the power conversion circuit each function normally.

6. The apparatus of claim 5, wherein the detection circuit is further configured to generate the second plot based on a second vector derived by the equation, a corresponding second amplitude and a corresponding second phase angle of the second vector being calculated through the first to third signals that are measured during operation of the power conversion circuit.

7. The apparatus of claim 6, wherein the detection circuit is further configured to determine the anomaly, in response to identifying an inconsistence between the first plot and the second plot.

8. The apparatus of claim 7, wherein the inconsistence occurs between the first amplitude and the second amplitude.

9. The apparatus of claim 8, wherein, based on the identified inconsistence, the detection circuit is further configured to determine that the anomaly results from one of the plurality of switches being abnormally open.

10. The apparatus of claim 7, wherein the inconsistence occurs between the first phase angle and the second phase angle.

11. The apparatus of claim 10, wherein, based on the identified inconsistence, the detection circuit is further configured to determine that the anomaly results from one of the plurality of switches being abnormally short.

12. The apparatus of claim 1, wherein each of the plurality of switches includes an insulated gate bipolar transistor (IGBT).

13. A detection circuit, comprising:
an interface circuit configured to receive a first current signal (I_{Uav}), a second current signal (I_{Vav}), and a third current signal (I_{Wav}), wherein the first current signal is provided by a first pair of switches coupled to a supply voltage, the second current signal is provided by a second pair of switches coupled to the supply voltage, and the third current signal is provided by a third pair of switches coupled to the supply voltage;
a transformation circuit configured to: (i) convert the first to third current signals into two orthogonal components; (ii) generate a first plot and a second plot each based on the two orthogonal components; and (iii) identify an anomaly associated with at least one of the first to third pairs of switches based on comparing the first plot and the second plot; and
a drive circuit configured to adjust one or more of a plurality of control signals gating the first to third pairs of switches, respectively, based on the identified anomaly.

14. The detection circuit of claim 13, wherein each of the first to third pairs of switches includes an insulated gate bipolar transistor (IGBT).

15. The detection circuit of claim 13,
wherein a first one (I_{Dav}) of the two orthogonal components is represented as:
$${I}_{Dav} = \frac{√ 2}{√ 3} {I}_{Vav} - \frac{1}{√ 6} {I}_{Vav} - \frac{1}{√ 6} {I}_{Wav} ;$$
and
wherein a second one (I_{Qav}) of the two orthogonal components is represented as:
$${I}_{Qav} = \frac{1}{√ 2} {I}_{Vav} - \frac{1}{\sqrt{2}} {I}_{Uav} + {I}_{Q 0} .$$

16. The detection circuit of claim 15, wherein the transformation circuit is further configured to generate a vector having an amplitude (I_{Sav}) and a phase angle (∠θ_{Sav}) based on following equation:
$${I}_{Sav} = \sqrt{{1}_{Dav}^{2} + {I}_{Qav}^{2}} , {∠θ}_{Sav} = arctan \frac{{I}_{Qav}}{{I}_{Dav}} .$$

17. The detection circuit of claim 16, wherein the transformation circuit is further configured to:
generate the first plot based on a first vector derived by the equation, a corresponding first amplitude and a corresponding first phase angle of the first vector being calculated through the first to third signals that are simulated under an assumption that the first to third pairs of switches of a power conversion circuit each function normally;
generate the second plot based on a second vector derived by the equation, a corresponding second amplitude and a corresponding second phase angle of the second vector being calculated through the first to third signals that are measured during operation of the power conversion circuit; and
determine the anomaly, in response to identifying that an inconsistence between the first plot and the second plot exceeds a threshold.

18. A method, comprising:
receiving a first current signal (I_{Uav}), a second current signal (I_{Vav}), and a third current signal (I_{Wav}), wherein the first current signal is provided by a first pair of switches coupled to a supply voltage, the second current signal is provided by a second pair of switches coupled to the supply voltage, and the third current signal is provided by a third pair of switches coupled to the supply voltage;
converting the first to third current signals into two orthogonal components;
generating a first plot and a second plot each based on the two orthogonal components;
identifying an anomaly associated with at least one of the first to third pairs of switches based on comparing the first plot and the second plot; and
adjusting one or more of a plurality of control signals gating the first to third pairs of switches, respectively, based on the identified anomaly.

19. The method of claim 18, wherein each of the first to third pairs of switches includes an insulated gate bipolar transistor (IGBT).

20. The method of claim 18,
wherein a first one (I_{Dav}) of the two orthogonal components is represented as:
$${I}_{Dav} = \frac{√ 2}{√ 3} {I}_{Vav} - \frac{1}{√ 6} {I}_{Vav} - \frac{1}{√ 6} {I}_{Wav} ;$$
wherein a second one (I_{Qav}) of the two orthogonal components is represented as:
and
$${I}_{Qav} = \frac{1}{√ 2} {I}_{Vav} - \frac{1}{\sqrt{2}} {I}_{Uav} + {I}_{Q 0} ;$$
wherein the method further comprise generating a vector for constructing each of the first and second plots, the vector having an amplitude (I_{Sav}) and a phase angle (∠θ_{Sav}) based on following equation:
$${I}_{Sav} = \sqrt{{1}_{Dav}^{2} + {I}_{Qav}^{2}} , {∠θ}_{Sav} = arctan \frac{{I}_{Qav}}{{I}_{Dav}} .$$
